(19) United States
(12) Patent Application Publication
(10) Pub. No.: US 2013/0025685 A1
(43) Pub. Date: Jan. 31, 2013

(54) ORGANIC HETEROJUNCTION SOLAR CELL IN A SPACE INCLUDING AN ELECTRICALLY ACTIVE LAYER AND HAVING VERTICAL SEGREGATION

(71) Applicants: Solenn Berson, Chambery (FR); Severine Bailly, La Motte-Servolex (FR); Stephane Guillerez, Lepin Le Lac (FR); Noella Lemaitre, Chambery (FR)

(72) Inventors: Solenn Berson, Chambery (FR); Severine Bailly, La Motte-Servolex (FR); Stephane Guillerez, Lepin Le Lac (FR); Noella Lemaitre, Chambery (FR)

(73) Assignee: COMMISSARIAT A L'ENERGIE ATOMIQUE ET AUX ENERGIES ALTERNATIVES, Paris (FR)

(21) Appl. No.: 13/641,903

(22) PCT Filed: Apr. 20, 2011
(86) PCT No.: PCT/FR2011/000239

§ 371 Date: Oct. 18, 2012

(30) Foreign Application Priority Data
Apr. 22, 2010 (FR) 10/01727

(51) Int. Cl. H01L 51/46; B82Y 99/00

(52) U.S. Cl. 136/263; 977/948

(57) ABSTRACT

The electrically active layer of an organic heterojunction solar cell is associated with an additional layer, so as to promote the vertical segregation between the p-type organic semiconductor material and the n-type carbonaceous semiconductor material that are present in the electrically active layer. The additional layer is in direct contact with the electrically active layer. Said additional layer comprises a compound forming noncovalent interactions with the n-type semiconductor carbonaceous material. In particular, said compound can be P4VP when the electrically active layer is formed of a mixture of P3HT:PCBM. Moreover, said additional layer comprises a n-type semiconductor material.

### TECHNICAL FIELD OF THE INVENTION

The invention relates to a bulk heterojunction organic solar cell.

### STATE OF THE ART

The development of organic electronic devices, such as organic transistors (OFET), organic light-emitting diodes (OLED), organic solar cells (OPV or organic photovoltaic cells), is at an industrial or preindustrial stage.

However, the active materials as well as the architectures of the devices still are in the process of evolution, in order to meet the criteria of performances and lifespan allowing to widen the fields of application of these technologies. In particular, it is desirable to try to improve the outputs and the stability of the current devices.

In some cases, the core of the organic electronic devices comprises an electrically active layer, also called active layer and formed by a wet process using a mixture containing at least two semiconductor materials of n-type (electron acceptor) and of p-type (electron donor), respectively. It is in particular the case for volume heterojunction organic solar cells (also called “bulk heterojunction OPV Devices”), light-emitting diodes and ambipolar organic transistors. However, the organization of the n-type and p-type semiconductor materials within the active layer, corresponding to the morphology of the active layer, is of paramount importance for the proper functioning of the electronic devices.

In particular, in the case of bulk heterojunction organic solar cells, the morphology of the mixture forming the electrically active layer is of paramount importance to obtain good charge transfers and transports and thus high conversion efficiencies.

As an example, a bulk heterojunction organic solar cell with a standard structure, according to the prior art, is illustrated in FIG. 1. This cell is made of a multi-layer stack comprising successively:

a substrate 1, made for example of glass or plastic,

a first electrode 2, for example a thin layer made of indium tin oxide (ITO),

a hole injection layer 3, made for example out of poly(3,4-ethylenedioxythiophene):poly(styrene-sulphonate) known under the name PEDOT:PSS,

an electrically active layer 4, obtained by mixing p-type and n-type semiconductor organic materials, for example by mixing P3HT (poly(3-hexylthiophene) and PCBM ([6,6]-phenyl-C61-methyl butyrate) and comprising opposite faces 4a and 4b

and a second electrode 5 made of electrically conducting material, such as a thin calcium/aluminum bilayer.

In this embodiment, the first and second electrodes 2 and 5 form an anode and a cathode, respectively.

Various factors were reported in the literature as being parameters which influence the morphology of the active layer 4. These parameters are generally related to the method of making the organic solar cell, and in particular to the nature and the properties of the initial solution used to form the active layer 4, as well as to the kinetic parameters playing a part in the formation of the active layer 4 and to the techniques of deposition.

All these parameters must be controlled in order to obtain an optimal morphology and more particularly the largest possible contact surface with the cathode for the n-type semiconductor material and the largest possible contact surface with the anode for the p-type semiconductor material, in order to get a good charge extraction at each electrode.

Thus, as reported in the article “Three-Dimensional Nanoscale Organization of Bulk Heterojunction Polymer Solar Cells” by Svetlana S. van Bevel and al. (Nano Letters 2009 Vo. 9, No 2, 507-513), an active layer in a bulk heterojunction organic photovoltaic cell with a standard structure ideally comprises a network made of the n-type semiconductor material and a network made of the p-type semiconductor material, with respective opposite concentration gradients for each p-type or n-type semiconductor material through the thickness of the active layer. Such a mixture morphology corresponds to a vertical segregation of the p-type and n-type semiconductor materials.

In the above-mentioned article, Svetlana S. van Bavel and al. observed such a vertical segregation by modifying certain conditions during the manufacturing process, and in particular by carrying out a thermal annealing or a solvent-assisted annealing, for bulk heterojunction organic solar cells with a standard structure. The cells were made from a mixture containing P3HT and PCBM dissolved in ODCB (orthodichlorobenzene), with a weight ratio of 1:1 and a total concentration of 20 mg/ml. The mixture was deposited by spin-coating, at a speed of 500 rpm onto a glass substrate 1 covered with an ITO layer 2 and a PEDOT:PSS layer 3 having a thickness of 70 nm. An improvement of the morphology of the active layer 4 is observed by electronic tomography for cells that have undergone a thermal annealing process at 130° C. for 20 minutes or a solvent-assisted annealing process for 3 hours.

For illustrative purposes, the active layer 4 represented in FIG. 1 and corresponding to the embodiment described in the article by Svetlana S. van Bavel and al. presents a vertical segregation between the p-type semiconductor material and the n-type semiconductor material. Such a vertical segregation is more particularly represented in FIG. 1 by a progressive gradation from black to bright gray, from the face 4b of the active layer 4 until the opposite face 4a. Such a gradation thus illustrates a concentration of the p-type semiconductor material (for example P3HT) and a concentration of the n-type semiconductor material (PCBM), respectively decreasing and increasing from the face 4a to the face 4b of the active layer 4.

In addition, in the article “Morphology Control in Solution-Processed Bulk Heterojunction Solar Cell Mixtures” (Adv. Funct. Mater, 2009, 19, 3028-3026), Adam J. Moulé and al. go through the techniques, developed these last years, for controlling the morphology of the polymer/fullerene mixtures forming an active layer in a bulk heterojunction cell with a standard structure and thus for obtaining improved efficiencies. In particular, they mentioned techniques implementing suspensions of polymer nanoparticles. As an example, such a technique is reported in the article “Poly(3-hexylthiophene) fibers for Photovoltaic Applications” by Solenn Berson and al. (Adv. Funct. Mater 2007, 17, 1377-1384). Adam J. Moulé and al. also mention the use of mixtures of solvents or additives to be added to the solvent. As an example, in the article “Processing Additives for Improved Efficiency from Bulk Heterojunction Solar Cells” (J. Am. Chem. SOC. 2008, 130, 3619-3623), Jae Kwan Lee and al. studied the criteria allowing to choose an additive in the class of 1,8-di(R)octanes, to be added to the initial solution for controlling the morphology of an active layer in PCPDTBT ([2,6-(4,4-bis(2-ethyl hexyl)-4 H-cyclopenta [2, 1-b;3,4-b′]-dithiophene)-alt-4,7-(2,1,3-benzothiadiazole)]) and in C₇₁-PCBM.

In addition, there exists bulk heterojunction cells with a structure different from the standard structure as represented in FIG. 1. Such cells are known as bulk heterojunction cells with an inverted structure. They were reported for example in the second part of the article “Recent Progress in Polymer Solar Cells: Manipulation of Polymer: Fullerene Morphology and the Formation of Efficient Inverted Polymer Solar Cells” by Li-Min Chen and al. (Adv. Mater 2009, 21, 1-16). Compared to bulk heterojunction cells with a standard structure, they are characterized in that:

the cathode (reference 5 in FIG. 1) of the standard structure is replaced by a PEDOT:PSS or a transition metal oxide layer having a high work function (for example V₂O₅ or MoO₃) and covered by an electrode made from a stable metal such as gold or silver

and the PEDOT:PSS layer (reference 3 on FIG. 1) disposed in the standard structure between the ITO layer (reference 2 in FIG. 1) and the active layer (reference 4 in FIG. 1) is replaced with another functional buffer layer, for example constituted by a compound having a low work function. Such a buffer layer allows the collection of electrons, so that it plays the part of a cathode in the inverted structure.

Thus, as the polarity of a bulk heterojunction cell is controlled by the relative positions of the functional layers having different work functions, the polarity of the cells having an inverted structure is inverted with respect to that of the cells with a standard structure, independently of the conducting electrodes.

At present, the bulk heterojunction cells with an inverted structure have a performance lower than that of the bulk heterojunction with a standard structure, because the methods of manufacturing thereof are not optimized yet. Indeed, the stacking process for the various thin layers differs according to the standard or inverted structure of the bulk heterojunction cell. Moreover, as bulk heterojunction cells with an inverted structure are less powerful, no research has been undertaken, to our knowledge, for favoring the vertical segregation in the active layer of the bulk heterojunction cells with an inverted structure.

Document US2008/142079 describes a photovoltaic cell comprising a first electrode, a second electrode, a photoactive layer disposed between the first and second electrodes, and a polar organic layer disposed between the photoactive layer and at least one of the first and second electrodes. The presence of the polar organic layer would allow, according to document US2008/142079, to significantly increase the photocurrent density of the cell.

### OBJECT OF THE INVENTION

The objective of the invention is to propose a bulk heterojunction organic solar cell whose performance is improved with respect to the bulk heterojunction organic solar cells according to the prior art.

According to the invention, this objective is reached by the annexed claims.

### SUMMARY DESCRIPTION OF THE DRAWINGS

Other advantages and features will more clearly arise from the following description of particular embodiments of the invention given as nonrestrictive examples and represented in the annexed drawings, in which:

FIG. 1 represents a bulk heterojunction organic solar cell with a standard structure according to the prior art.

FIG. 2 represents a particular embodiment of a bulk heterojunction organic solar cell with an inverted structure according to the invention.

FIG. 3 illustrates an alternative embodiment of a cell according to FIG. 2.

FIG. 4 represents the evolution of the conversion efficiency η (in %) as a function of time for four organic solar cells: two cells according to the invention, each comprising an additional layer containing P4VP and PCMB (Cells A1 and B1) and two cells according to the prior art (cells C1 and D1).

FIG. 5 represents the evolution of the conversion efficiency η (in %) as a function of time for six organic solar cells: five cells according to the invention, each comprising an additional layer containing of P4VP and ZnO (Cells A1 to E1) and one cell according to the prior art (cell F1 airframe).

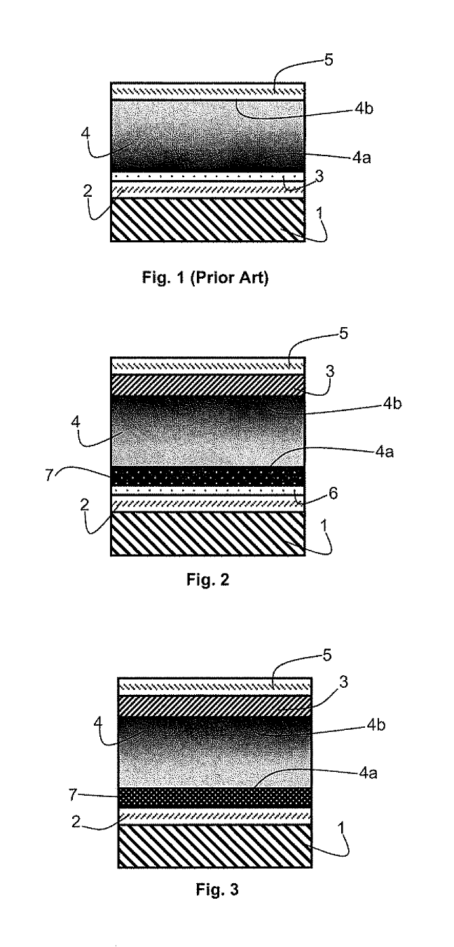

### DESCRIPTION OF PARTICULAR EMBODIMENTS

The electrically active layer of a bulk heterojunction organic solar cell is associated with an additional layer, in order to favor the vertical segregation between the p-type organic semiconductor material and the n-type carbonaceous semiconductor material that are present in the electrically active layer.

The n-type carbonaceous semiconductor material contained in the active layer is advantageously selected among:

fullerenes, for example fullerene C60, fullerene C70, fullerene C80 or fullerene C84,

carbon semiconductor nanotubes,

graphene and nanographenes,

and soluble derivatives thereof, such as [6,6]-phenyl-C61-methyl butyrate also known under the name PCBM or PC₆₁BM, [6,6]-phenyl-C71-methyl butyrate or PC₇₁BM, a thiophene-C61-methyl butyrate, a multi-adduct of a fullerene C60 or C70 or functionalized carbon nanotubes.

The p-type semiconductor organic material contained in the active layer is selected among polymers or copolymers containing thiophene, carbazole, benzothiadiazole, cyclopentadithiophene, diketopyrrolopyrrole. For example, it comprises (poly(3-hexylthiophene) also known under the name P3HT.

More particularly, the additional layer comprises a compound specifically selected for its capacity to form noncovalent interactions with the n-type semiconductor carbonaceous material present in the electrically active layer. The additional layer can also be called “carbophilic layer” as it presents a certain affinity with the carbon of the n-type carbonaceous semiconductor material present in the electrically active layer. Moreover, the additional layer is in direct contact with the electrically active layer. Consequently, no intermediate layer is disposed between the electrically active layer and the additional layer.

For the above-mentioned n-type semiconductor carbonaceous materials, the compound forming noncovalent interactions with the n-type semiconductor carbonaceous material and present in the additional layer is more particularly a polymer selected among:

fluorinated polymers, for example selected among vinylidene polyfluoride, a polytetrafluoroethylene, a copolymer of tetrafluorethylene and perfluorovinylether.

and polymers having side chains comprising at least one nitrogenized aromatic group, advantageously, selected among pyridine, pyrimidin, pyrazine, pyridazin and triazine. The compound can be for example a polymer selected among polyvinylpyrimidins, polyvinylpyrazins, polyvinylpyridazins, poly(2-vinyl-pyridine) and poly(4-vinyl-pyridine) also designated P4VP.

In addition, the additional layer disposed in a bulk heterojunction organic solar cell comprises a n-type semiconductor material, in addition to the compound forming noncovalent interactions with the n-type semiconductor carbonaceous material contained in the electrically active layer. In particular, the n-type semiconductor material contained in the additional layer can be a n-type semiconductor element acting as a doping agent, such as PCBM. It can also be an n-type inorganic semiconductor material, such as ZnO or TiOx. In this latter case, the additional layer can act as an electron injection layer, directly disposed between the cathode and the electrically active layer.

Thus, associating such an additional layer with the electrically active layer of a bulk heterojunction organic solar cell allows to favor the vertical segregation between the p-type organic semiconductor material and the n-type carbonaceous semiconductor material that are present in the electrically active layer.

Such an association advantageously corresponds to a direct contact of the electrically active layer with said additional layer when manufacturing the bulk heterojunction organic solar cell. Thus, the vertical segregation is more particularly favored and obtained during the formation of the active layer by a wet process from a homogeneous mixture containing the n-type and p-type semiconductor materials, directly on the previously formed additional layer.

In particular, the electrically active layer can be formed on the additional layer by various methods of depositing a liquid mixture comprising semiconductor materials, respectively p-type and n-type, such as spin-coating, coating or a printing method such as techniques of ink jet printing, screen printing, heliography printing . . . It can then be submitted to a step of heat treatment in order to further improve the vertical segregation. The heat treatment is carried out for example between 50° C. and 180° C., for a length of time between 1 minute and 30 minutes.

Moreover, the additional layer, formed before the active layer, can also be carried out by various methods of depositing a solution containing the compound intended to form noncovalent interactions with the n-type semiconductor carbonaceous material.

In particular, such a compound is dissolved with the n-type semiconductor material used in the composition of the additional layer. When the n-type semiconductor material is a doping element for the additional layer, this additional layer has advantageously a thickness lower than 5 nm. Otherwise, the additional layer has advantageously a thickness between 5 nm and 50 nm. Moreover, according to its nature, the compound can also be in a liquid or powder form. In addition, the techniques of depositing the solution intended to form the additional layer on a support can be the same ones as those used to form the electrically active layer (spin-coating, coating, ink jet printing, screen printing or heliography printing. Lastly, once the additional layer is formed and before the electrically active layer is deposited, the additional layer can be submitted in some cases to a thermal annealing between 25° C. and 450° C.

The support the additional layer is deposited on depends on the type of bulk heterojunction organic solar cell one wishes to elaborate. In particular, the additional layer can be deposited directly on one of the two electrodes (in particular the cathode) of the organic solar cell or, of course, on an intermediate thin layer, which is in contact with said electrode. The intermediate layer is more particularly formed by a n-type semiconductor material.

As an example, the support the additional layer is formed on can be for example a multi-layer stack formed by a substrate made of glass or plastic, a thin layer made of an electrically conducting material forming an electrode (and forming more particularly the cathode) and possibly an intermediate thin layer.

Thus, during the formation of the active layer on the additional layer, the n-type carbonaceous semiconductor material present in the solution intended to form the active layer is spontaneously attracted by the interface between said solution and is the additional layer, while the p-type semiconductor material tends to move in the opposite direction. Thus, the respective distributions of the n-type semiconductor carbonaceous material and the p-type semiconductor organic material in the electrically active layer will be spontaneously and naturally disturbed, during the formation of the electrically active layer on the previously formed additional layer. In particular, the presence of the additional layer will allow to obtain:

a concentration for the n-type semiconductor carbonaceous material, decreasingly varying in the electrically active layer, from the face of the active layer in contact with the additional layer to the opposite face of said active layer,

and a concentration for the p-type semiconductor organic material, increasingly varying in the electrically active layer, from the face of the active layer in contact with the additional layer to the opposite face of said active layer.

More particularly, regarding the face of the electrically active layer which is in direct contact with the additional layer, the proportion of n-type semiconductor carbonaceous material is higher than 50% by weight with respect to the total weight of the electrically active layer. Conversely, regarding the opposite face of the active layer, it is the proportion of p-type semiconductor organic material that is higher than 50% by weight with respect to the total weight of the electrically active layer.

Such an arrangement is particularly advantageous for the bulk heterojunction organic solar cells. Indeed, achieving such a vertical segregation in the active layer of a bulk heterojunction organic solar cell ensures in particular the improvement of the performance of the cells and more particularly the achieving of a good conversion efficiency. The conversion efficiency is more particularly designated by η and is determined by the following formula: η=(Voc*Jsc*FF)/P wherein Voc corresponds to the open-circuit voltage, Jsc corresponds to the short-circuit current density, FF is the form factor of the cell and P is the incident power. In general, it is measured under an illumination AM 1.5 having an incident power of 100 mW.cm⁻² and is expressed as a percentage.

In particular, the insertion of the additional layer allows to support a morphology according to which the semiconductor materials of n-type and p-type, respectively, have great surfaces of contact with the layers disposed on the cathode and anode sides, respectively.

As example, a first particular embodiment of a bulk heterojunction organic solar cell with an inverted structure is represented in FIG. 2.

In particular, a cell comprises a multi-layer stack formed by:

a substrate 1, made for example of glass,

a thin layer 2 made of an electrically conducting material, such as indium tin oxide (ITO) and forming a first electrode,

an intermediate thin layer 6 made of a n-type semiconductor material made for example of zinc oxide (ZnOₓ) or of titanium oxide (TiOₓ) and forming an electron injection layer,

an additional layer 7, made for example of P4VP (or poly(4-vinylpyridine)) doped by PCBM (designated by P4VP+PCBM hereafter),

an electrically active layer 4, made for example of a mixture of P3HT and PCBM (designated by P3HT:PCBM hereafter),

a thin layer 3 made of a p-type semiconductor material, such as poly(3,4-ethylenedioxythiophene):poly(styrene-sulphonate) known under the name PEDOT:PS or NiO, or CuOₓ and forming a hole injection layer,

and a thin layer 5 made of an electrically conducting material, such as silver and forming a second electrode made of an electrically conducting material.

In this particular embodiment, the first and second electrodes 2 and 5 form the cathode and the anode of the cell, respectively.

A bulk heterojunction organic solar cell with a particular inverted structure, according to FIG. 2, can be obtained for example according to a manufacturing method including the following successive steps:

Step 1: the intermediate thin layer 6, made for example of ZnO, is formed by spin-coating deposition, from a precursor solution, onto a thin ITO layer 2 covering a glass substrate 1. The deposition is carried out for 60s at a speed of 1000 rpm, then for 30 s at a speed of 2000 rpm. Moreover, the deposition is carried out under air and the thickness of the obtained intermediate thin layer 6 is approximately of 15 nm. The deposition is followed by a drying phase in an annealing process carried out by means of a hotplate, at a temperature of 150° C. for 1 h.

Step 2: a solution containing a mixture of P4VP+PCBM (1 g/L of P4VP in isopropanol with a ratio of 10 w % of PCBM with respect to the weight of P4VP) is deposited, by spin-coating, onto the intermediate thin layer 6, once the latter is dried, at a speed of 5000 rpm for 25 s, then at a speed of 4000 rpm for 25 s. The deposition is followed by a drying phase in an annealing process carried out by means of a hotplate, at a temperature of 150° C. for 15 minutes. The additional layer 7 has a thickness lower than 5 nm.

Step 3: the deposition of the electrically active layer 4 is carried out onto the additional layer 7, by spin coating deposition of a composition of P3HT:PCBM, at a speed of approximately 1500 rpm for 40 s, then at a speed of 2000 rpm for 35 s. The thickness of the obtained active layer 4 is comprised between 200 and 250 nm and the weight ratio between P3HT and PCBM is 1:1.

Step 4: the hole injection layer 3 is deposited by spin coating onto the active layer 4, at a speed of 2000 rpm for 25 s, then at a speed of 3000 rpm for 25 s. The hole injection layer 3 has a thickness of approximately 50 nm. The stacking thus obtained is then disposed in a glove box, to be submitted therein to an annealing process for 15 minutes at 150° C.

Step 5: a thin layer 5 made for example of silver and having a thickness of 100 nm is then deposited by vacuum evaporation.

In this embodiment, the additional layer 7 is formed on an intermediate thin layer 6 made of a n-type semiconductor material disposed on the thin layer 2 made of an electrically conducting material forming the first electrode (cathode) of the bulk heterojunction cell with an inverted structure.

However, in some embodiments, the additional layer 7 can be formed and thus disposed directly onto the thin layer 2 made of an electrically conducting material, forming the first electrode and more particularly forming the cathode of the cell. In particular, it is the case in the alternative embodiment represented in FIG. 3.

In this case, the additional layer 7 advantageously comprises, in addition to the compound forming noncovalent interactions with the n-type semiconductor carbonaceous material present in the active layer 4 (for example P4VP or P4VP+PCBM), a n-type inorganic semiconductor material, such as zinc oxide or titanium oxide, so that it can then also act as an electron injection layer.

As an example, a bulk heterojunction organic solar cell according to FIG. 2 can be obtained in particular by spin coating deposition of a precursor solution containing the n-type semiconductor material (for example ZnO) and the compound (for example P4VP) favoring the covalent interactions with the n-type semiconductor material present in the active layer 4, directly onto an ITO electrode 2 covering a substrate 1, made for example of glass. In particular, for obtaining an additional layer 7 containing ZnO and 5 w % of P4VP, the precursor solution can be obtained by mixing and agitating for 2 days 1 mL of a first solution of P4VP at 1 g/L prepared in isopropanol and 1 ml of a second solution containing a zinc precursor prepared at 20 g/L in an alcoholic solution such as 2-methoxyethanol/ethanolamine. Moreover, the spin coating deposition of the precursor solution is advantageously carried out under air for 60s at a speed of 1000 rpm, then for 30s at a speed of 2000 rpm, in order to obtain a thickness of approximately 15 nm. The additional layer 7 is then dried by means of a hotplate at a temperature of 150° C. for 1 h. As the following steps allows to form the active layer 4, the hole injection layer 3 and the second electrode 5 can be identical to those carried out for the cell according to FIG. 2.

Several series of photovoltaic cells, obtained according to above-described embodiments and represented in FIGS. 2 and 3, were made in order to measure their performance from both photovoltaic conversion efficiency and time stability.

A set (designated by set 1 hereafter) of two cells was carried out and tested with an additional layer made of P4VP and doped with 10% of PCBM (cells A1 and B1), for various weight ratios for the mixture P3HT:PCBM contained in the electrically active layer 4. Two cells, without additional layer and with weight ratios of 1:1 and 1:0.6, respectively, between P3HT:PCBM (cells C1 and D1) were also carried out and tested under the same conditions as for the cells of the set 1.

More particularly, the table 1 below shows the technical characteristics of the above-mentioned cells:

TABLE 1

| | | |
|---|---|---|
| | | Weight ratio |
| Solar cell tested | Additional layer | P3HT:PCBM |

| | | | |
|---|---|---|---|
| Set 1 | A1 | P4AVP + PCBM | 1:0.6 |
| | B1 | P4AVP + PCBM | 1:1 |

| | | |
|---|---|---|
| C1 (control) | None | 1:0.6 |
| D1 (control) | None | 1:1 |

Once made, all these cells were disposed in a glove box under controlled atmosphere, in order to be tested under continuous illumination.

In particular, the current-voltage characteristics (I(V)) of these cells were recorded on a Current-Voltage measurement device marketed by Keithley Instruments Sari under the model SMU 2400, when they are submitted to an illumination AM1.5 at a power of 1000 W.m⁻².

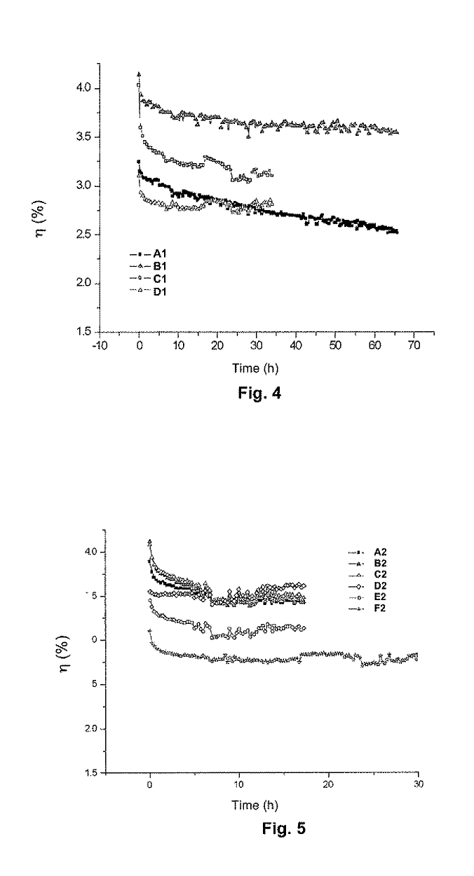

The evolution of the conversion efficiency η as a function of the exposure time under illumination AM1.5 is reported for each cell of table 1 in FIG. 4 (cells A1 to D1).

The tests carried out enable to show that the efficiency values obtained with the additional layer made of P4VP+PCBM (Curves A1 and B1) are higher than the efficiency values obtained without the additional layer (Curves C1 and D1) during the exposure time. The efficiency is even higher than that of a control cell, for a weight ratio of 1:1 of P3HT:PCBM in the electrically active layer 4. However, this ratio is particularly interesting for the ageing stability of the cell (good time stability of the efficiency). Moreover, these efficiency values remain stable in time.

Thus, the variation of the conversion efficiency at t=0 was studied as a function of the percentage of PCBM introduced into the additional layer, for an active layer containing a weight ratio of 1:1 for the mixture P3HT:PCBM. The results are reported in table 2 below.

TABLE 2

| % PCBM in the additional layer | Conversion efficiency |
|---|---|
| 5 | 2.74% |
| 10 | 3.30% |
| 15 | 2.84% |
| 20 | 3.21% |

Thus, a concentration of approximately 10% of PCBM in the additional layer enables to obtain an optimal conversion efficiency while keeping a good time stability, considering the weight ratio of 1:1 for the mixture P3HT:PCBM used for the active layer.

In addition, a set (designated by set 2 hereafter) of bulk heterojunction organic solar cells according to the embodiment represented in FIG. 3 was carried out according to step 1 with percentages of P4VP varying from 2.5 w % to 10 w % of P4VP with respect to the weight of the ZnO precursor in solution, in an additional layer made of ZnO and P4VP (cells A2 to E2), for an active layer comprising a mixture P3HT:PCBM with a weight ratio of 1:1. Moreover, for comparison purposes, a cell comprising only one ZnO layer disposed between the cathode and the active layer (cell F2) was carried out under the same conditions as the cells of set 3. Thus, this cell F2 corresponds to a cell according to FIG. 3 in which the additional layer 7 would comprise no P4VP.

The cells A2 to F2 were tested with a continuous illumination under the same conditions as set 1 and the evolution of the conversion efficiency η in % as a function of the exposure time is reported for each cell A2 to F2 in FIG. 5. The initial photovoltaic conversion efficiency (at t=0) for the cells A2 to E2 is moreover reported in table 3 below as well as the technical characteristics of each cell:

TABLE 3

| Tested solar cell | | Additional layer | η(%) |
|---|---|---|---|
| Set 2 | A2 | ZnO + 2.5% PAVP | 3.4 |
| | B2 | ZnO + 5% PAVP | 3.4 |
| | C2 | ZnO + 5% PAVP | 3.4 |
| | D2 | ZnO + 7.5% PAVP | 3.2 |
| | E2 | ZnO + 10.5% PAVP | 3.15 |

| | | |
|---|---|---|
| F2 (control) | ZnO | 2.45 |

Thus, the results reported in table 3 above enable to note that, in the same way as for the preceding cells, the cells A2 to E2 have increased performance with respect to the control cell. Indeed, it is noted that adding the compound P4VP into the ZnO layer allows to obtain an increase in the conversion efficiency with respect to a cell according to the prior art. Moreover, the curves obtained in FIG. 6 show a time stability of the cells comprising an additional layer with ZnO and a non-zero percentage of P4VP.

Lastly, tests were also carried out in order to evaluate the role of the weight ratio of P3HT:PCBM (1:1, 1:0.8 and 1:0.6) in the active layer 4 for four categories of organic solar cells:

a) a category of control cells comprising an intermediate ZnO layer and without additional layer (designated by ZnO alone hereafter)

b) a category of cells comprising an intermediate ZnO layer and an additional P4VP layer (designated by ZnO/P4VP hereafter)

c) a category of cells such as those made for set 1, i.e. with an intermediate ZnO layer and an additional P4VP+PCBM layer (designated by ZnO/P4VP+PCBM hereafter) with, in the same way as for cells A1 and B1, a percentage of 10% of PCBM.

d) a category of cells such as those made for set 2, i.e. without intermediate ZnO layer but with an additional layer containing ZnO and 5 w % of P4VP (designated by ZnO4-P4VP hereafter).

Table 4 below shows the initial photovoltaic conversion efficiencies (at t=0) obtained for these various categories of organic solar cells.

TABLE 4

| | Photovoltaic conversion efficiency | | |
|---|---|---|---|
| | P3HT:PCBM | P3HT:PCBM | P3HT:PCBM |
| Type of cell | 1:1 | 1:0.8 | 1:0.6 |
| ZnO | 2.45% | 3.49% | 3.71 |
| ZnO/P4VP | 3.87% | 3.79% | 3.72% |
| ZnO/P4VP + PCBM | 3.65% | 3.13% | 3.37% |
| ZnO + P4VP | 3.40% | 3.63% | 3.41% |

In the presence of an additional layer, all the efficiencies obtained are higher than 3%, whatever the ratio between P3HT and PCBM in the active layer. This is all the more interesting because it is well-known in the prior art that, that by increasing the quantity of PCBM, the device is more stable in time but it loses its initial performance (case of ZnO in table 4). In addition, the tests carried out show the time stability of the cells, in particular those comprising an additional layer made of P4VP+10% of PCBM (FIG. 5).

1-15. (canceled)

16. Bulk heterojunction organic solar cell comprising:
first and second electrodes,
an electrically active layer, disposed between the first and second electrodes and comprising
a p-type semiconductor organic material and
a n-type semiconductor carbonaceous material selected among fullerenes, carbon nanotubes, graphene and nanographenes, and soluble derivatives thereof,
an additional layer, disposed between the first electrode and the electrically active layer, in direct contact with the electrically active layer, and comprising
a n-type semiconductor material and
a compound forming noncovalent interactions with the n-type semiconductor carbonaceous material and selected among fluorinated polymers and polymers having side chains comprising at least one nitrogenized aromatic group.

17. Cell according to claim 16, wherein the concentration of the n-type semiconductor carbonaceous material decreasingly varies in the electrically active layer, from a first face of the electrically active layer in contact with the additional layer to a second face of the electrically active layer, opposite to the first face.

18. Cell according to claim 17, wherein the concentration of the p-type semiconductor organic material increasingly varies in the electrically active layer, from a first face of the electrically active layer in contact with the additional layer to a second face of the electrically active layer, opposite to the first face.

19. Cell according to claim 16, wherein the n-type semiconductor carbonaceous material is PCBM.

20. Cell according to claim 16, wherein the at least one nitrogenized aromatic group is selected among pyridine, pyrimidine, pyrazine, pyridazine and triazine.

21. Cell according to claim 16, wherein the compound forming noncovalent interactions with n-type semiconductor carbonaceous material is a polymer chosen among polyvinylpyrimidines, polyvinylpyrazines, polyvinylpyridazines, poly(2-vinyl-pyridine) and poly(4-vinyl-pyridine).

22. Cell according to claim 16, wherein the compound forming noncovalent interactions with n-type semiconductor carbonaceous material is a fluorinated polymer selected among vinylidene polyfluoride, polytetrafluoroethylene, copolymer of tetrafluorethylene and perfluorovinylether.

23. Cell according to claim 16, wherein the p-type semiconductor organic material is selected among polymers or copolymers containing thiophene, carbazole, benzothiadiazole, cyclopentadithiophene and diketopyrrolopyrrole.

24. Cell according to claim 23, wherein the p-type semiconductor organic material is P3HT.

25. Cell according to claim 16, wherein the additional layer is in direct contact with the first electrode.

26. Cell according to claim 25, wherein the compound contained in the additional layer is poly(4-vinyl-pyridine) and in that the n-type semiconductor material contained in the additional layer is selected among zinc oxide and titanium oxide.

27. Cell according to claim 16, wherein an intermediate thin layer, made of a n-type semiconductor material, is disposed between the additional layer and the first electrode.

28. Cell according to claim 27, wherein the compound forming noncovalent interactions with the n-type semiconductor carbonaceous material is poly(4-vinyl-pyridine) and in that the n-type semiconductor material is PCBM.
